(19) United States
(12) Patent Application Publication
(10) Pub. No.: US 2005/0066900 A1
(43) Pub. Date: Mar. 31, 2005

(54) Apparatus for forming the thin film on an organic light-emitting doide component

(76) Inventors: I-Ming Liu, Hsinchu City (TW); I-Cheng Kuo, Taichung (TW); Ming-Yang Chuang, Caotun Township (TW); Wei-Yang Cheng, Hsinchu City (TW)

Correspondence Address: BIRCH STEWART KOLASCH & BIRCH, PO BOX 747, FALLS CHURCH, VA, 22040-0747, US

(21) Appl. No.: 10/671,999

(22) Filed: Sep. 29, 2003

(51) Int. Cl. C23C 16/00

(52) U.S. Cl. 118/726

(57) ABSTRACT

An apparatus for forming the thin film on the organic light-emitting diode component includes an evaporation resource mechanism, a mixing chamber mechanism, a hollow revolving spindle mechanism, and a vacuum mechanism. The mixing chamber mechanism is coupled to the evaporation resource mechanism. The vacuum mechanism is coupled to the mixing chamber mechanism and is used for generating vacuum in the mixing chamber mechanism. The hollow revolving spindle mechanism has a hollow revolving spindle whose of one end is coupled to the mixing chamber mechanism, a revolving arm coupled to the other end of the hollow revolving spindle and having a surface and a plurality of spraying holes disposed on the surface, and a transmission mean having a driving resource and a transmitting body disposed around the hollow revolving spindle, such that the driving source drives the transmitting body and further the transmitting body drives the hollow revolving spindle.

### FIELD OF THE INVENTION

The present invention relates to an apparatus for forming the thin film on an organic light-emitting diode component and, more particularly, to an apparatus for forming the thin film on an organic light-emitting diode component has a rotating evaporation on a substrate to form a uniform thickness of a thin film.

### BACKGROUND OF THE INVENTION

According to the field of the semiconductor industry, the electronics industry and the mechanical industry, in order to make use components to have some properties, there is a typical method using an evaporation treatment which a thin film is deposited on the surface of the components.

The so-called evaporation is mainly constituted by an evaporation chamber for carrying out the evaporation and a vacuum system for providing the necessary vacuum for the evaporation. The used solid evaporation material is dispose in a crucible surrounded by the heating filament, and the filament, which is made of conduct electricity material, is electrically connected to an exterior direct current source. When suitable direct current flow through the filament, the heat generated by the resistance effect of the filament heats the evaporation material in the crucible until the temperature is near the melting point of the deposition material. Meanwhile, the evaporation material has a great capacity of the evaporation. The vapor (the molecule of the deposition material) which is evaporated is utilized to deposit the thin film on the surface of the substrate above of the deposition source.

There are typical manufacturing methods using a point evaporation, a line evaporation, an Organic vapor Phase Deposition (OVPD), and Deposition Scan Process (DSP).

Referring to FIG. 1, it is the structural schematic diagram of a conventional point evaporator. The conventional point evaporator has a crucible A and a substrate B to be evaporated which is disposed at a suitable position above the crucible. By a photo mask, the vapor D which is generated by the crucible A is evaporated to form a thin film.

The evaporated direction of the vapor is uncertain in the evaporation process, and therefore it is necessary that the substrate is rotated continuous to make the thickness of the thin film on the substrate B uniformly. Nevertheless, the substrate B must make a precision alignment for the photo mask, so the substrate B is as fixed as possible. If the substrate B is directly heated in the manufacturing process of the organic light-emitting, the density of the layer of the thin film can be increased and the life cycle of the component can be extended. Nevertheless, the substrate B is equipped with a heating pipe or a thermocouple in the manufacturing process with the rotated substrate B, designing the structure of the substrate B is very complex. In addition, when the point evaporator is resupplied with an evaporation material, the evaporation vacuum chamber generally need to be filled with nitrogen until the pressure of the chamber is equal to a atmospheric pressure, and therefore the usage efficiency of the evaporation material is very low.

Referring to FIG. 2, it is the structural schematic diagram of a conventional line evaporator. The line evaporation includes a crucible A1 is a rectangular form and differs from the point evaporation. The crucible is moved transversely by a linear slider E disposed under the crucible, and a substrate B1 above the crucible A1 is fixed. The line evaporation mainly utilizes the vapor D1 which is generated by the crucible A1 with the rectangular form is a rectangular shape, and the vapor is evaporated to form a thin film on the surface of the substrate B1 by the linear slider E moving transversely.

The line evaporation that the substrate B1 is fixed to increase the preciseness of the evaporation, but the disadvantage is that the linear slider E need an extra space to move transversely. Therefore, the volume of the line evaporator is about two times bigger than that of the convention evaporator (such as the point evaporator), so as to increase the cost of a clean room.

Referring to FIG. 3, it is the structural schematic diagram of a conventional OVPD device. The OVPD device mainly includes a vapor tank F which is provided with an evaporation material G and filled with a inert carrier gas H (such as N₂). A heater A2 disposed under the vapor tank F is used for heating the evaporation material G of the vapor tank F to form a vapor. The vapor D2 is carried into a plane shape sprayer J by the inert carrier gas H and further evaporated on the surface of a substrate B2 to form a thin film by using spraying holes K.

Nevertheless, a thermal energy is easy accumulated on the substrate B2 to cause a thermal damage because the plane shape sprayer J of the OVPD device has a very big surface and is very near the substrate B2. In addition, according to the sprayer which is fixed, in order to make the thickness of the thin film uniformly, the substrate B2 is required to be rotated continuously. For above reason, there is still the problem that the repeatability of an evaporation pattern is not enough. Furthermore, during the process of the thin film, the evaporation rate of any evaporation material is only calculated by the flow rate of the carrier gas H, and the calculated data cannot be feedback to an evaporation source for closed loop control. Besides, the substrate B2 is required to be rotated continuously, and therefore the substrate B2 still cannot be equipped with a heat and a thermocouple. For above reason, the density of the thin film cannot be increased during the manufacturing process of the organic light-emitting diode (OLED) component so as to limit the life cycle of the OLED component.

Referring to FIG. 4, it is the structural schematic diagram of a conventional DSP device. The DSP device mainly includes a sprayer which can be moved transversely. The formation of the vapor of the sprayer J1 of the DSP device is the same as that of the OVPD device. (Therefore, the inventor doesn't give unnecessary details again.) The vapor goes though a photo mask C3 and is evaporated on the surface of a substrate B3 to form a thin film.

Nevertheless, compares with the process of the thin film of “the line evaporator”, that of the DSP device has the same disadvantage, that the linear slider (not shown in figure) is also required to have an extra space to move transversely. Therefore, the volume of the DSP device is about two times bigger than that of the convention evaporator (such as the point evaporator), so as to increase the cost of a clean room.

In addition, compares with the process of the thin film of “the OVPD device”, that of the DSP device has the same disadvantage, that the evaporation rate of any evaporation material is only calculated by the flow rate of the carrier gas H, and the calculated data cannot be feedback to an evaporation source for closed loop control.

As described above, in order to make the thin film uniformly and increase the life cycle of the component, and solve the problem of the above-mentioned device, during the process of the thin film the substrate is as fixed as possible and the evaporation source is pivoted at a fixed point and is rotated.

Accordingly, there exists a need for an apparatus for forming the thin film on an organic light-emitting diode component to solve the above-mentioned problems and disadvantages.

### SUMMARY OF THE INVENTION

It is an object of the present invention to provide an apparatus for forming the thin film on an organic light-emitting diode component having a rotating evaporation on a substrate to form an uniform thickness of a thin film.

In order to achieve the foregoing objects, the present invention provides an apparatus for forming a thin film on the organic light-emitting diode component includes an evaporation resource mechanism, a mixing chamber mechanism, a hollow revolving spindle mechanism, and a vacuum mechanism. The mixing chamber mechanism is coupled to the evaporation resource mechanism. The vacuum mechanism is coupled to the mixing chamber mechanism and is used for generating vacuum in the mixing chamber mechanism. The hollow revolving spindle mechanism has a hollow revolving spindle whose of one end is coupled to the mixing chamber mechanism, a revolving arm coupled to the other end of the hollow revolving spindle and having a surface and a plurality of spraying holes disposed on the surface, and a transmission mean having a driving resource and a transmitting body disposed around the hollow revolving spindle, such that the driving source drives the transmitting body and further the transmitting body drives the hollow revolving spindle.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is the structural schematic diagram of a conventional point evaporator.

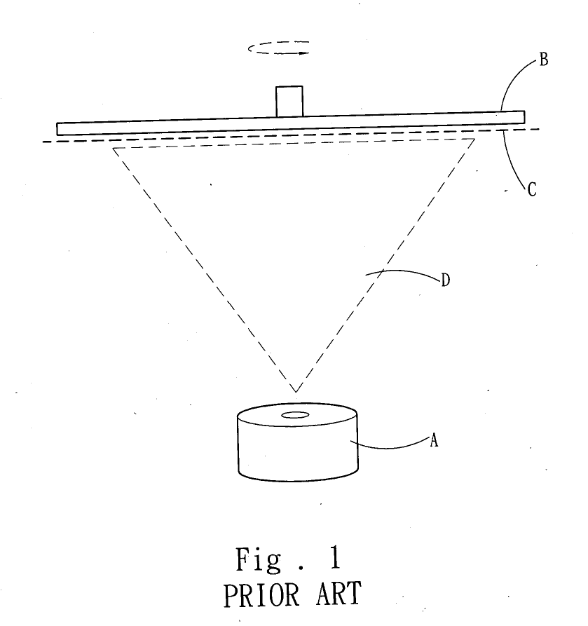

FIG. 2 is the structural schematic diagram of a conventional line evaporator.

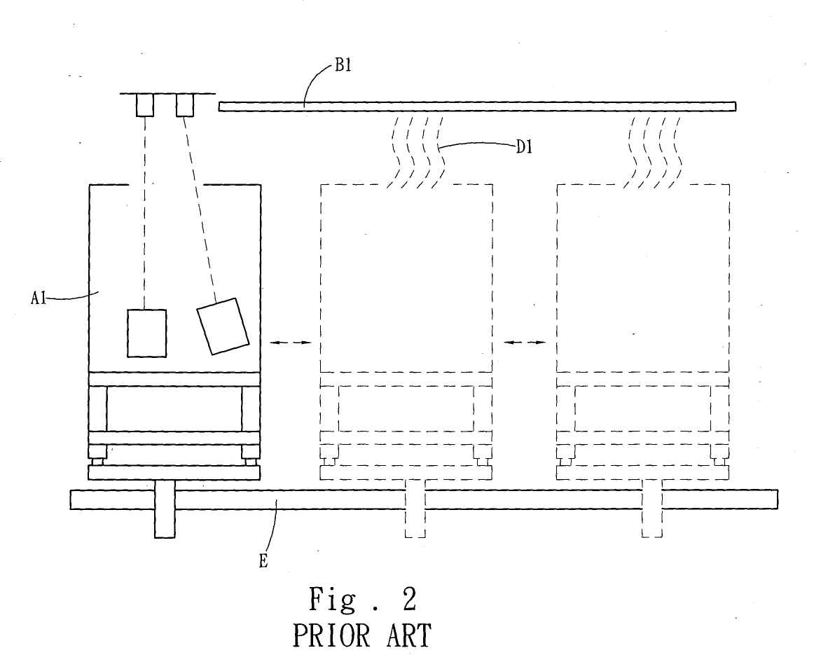

FIG. 3 is the structural schematic diagram of a conventional OVPD device.

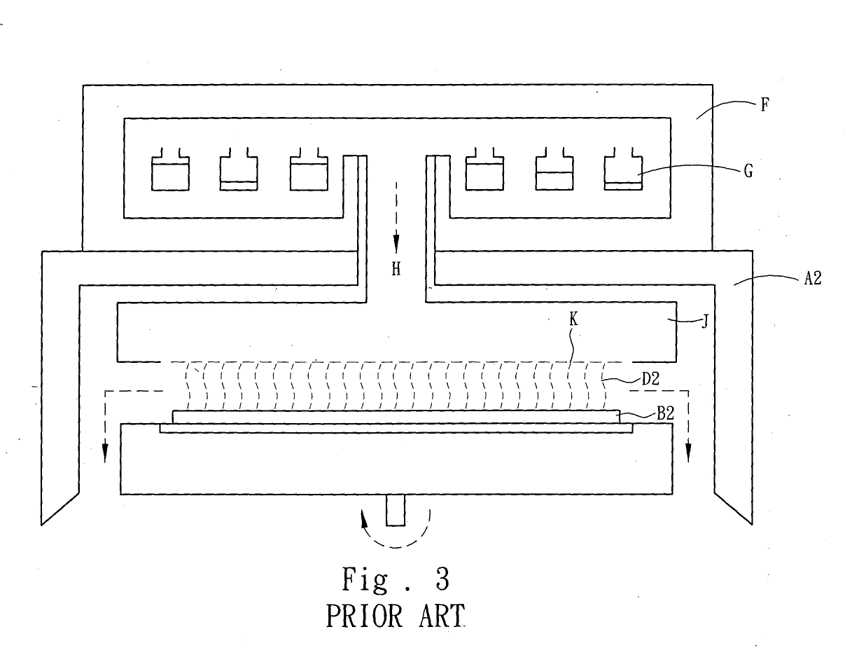

FIG. 4 is the structural schematic diagram of a conventional DSP device.

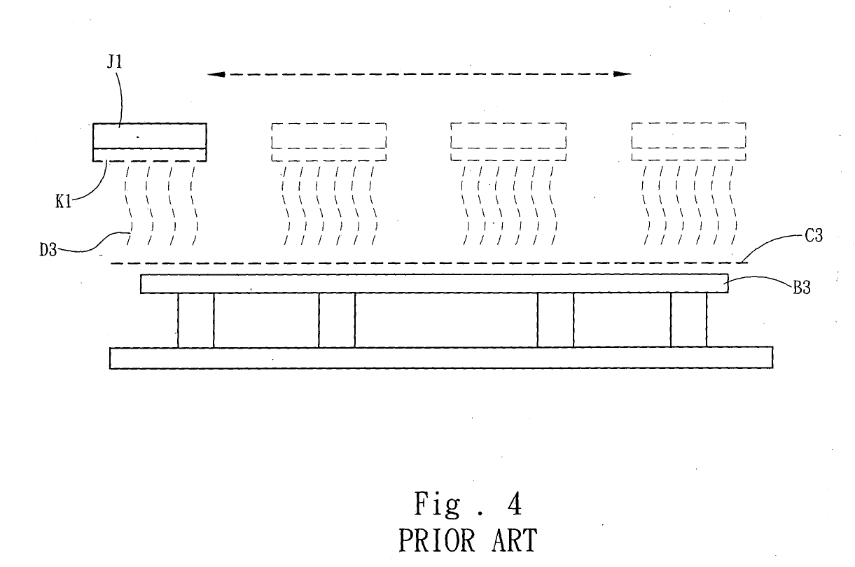

FIG. 5 is the structural schematic diagram of an apparatus for forming a thin film according to the present invention.

FIG. 6 is the schematic diagram of the revolving arm according to the present invention.

FIG. 7 is the schematic diagram of the mixing chamber mechanism according to the present invention.

FIG. 8 is another schematic diagram of the revolving arm according to the present invention.

FIG. 9 is another schematic diagram of the evaporation source mechanism according to the present invention.

FIG. 10 is another schematic diagram of the hollow revolving spindle according to the present invention.

### DETAIL DESCRIPTION OF THE PREFERRED EMBODIMENTS

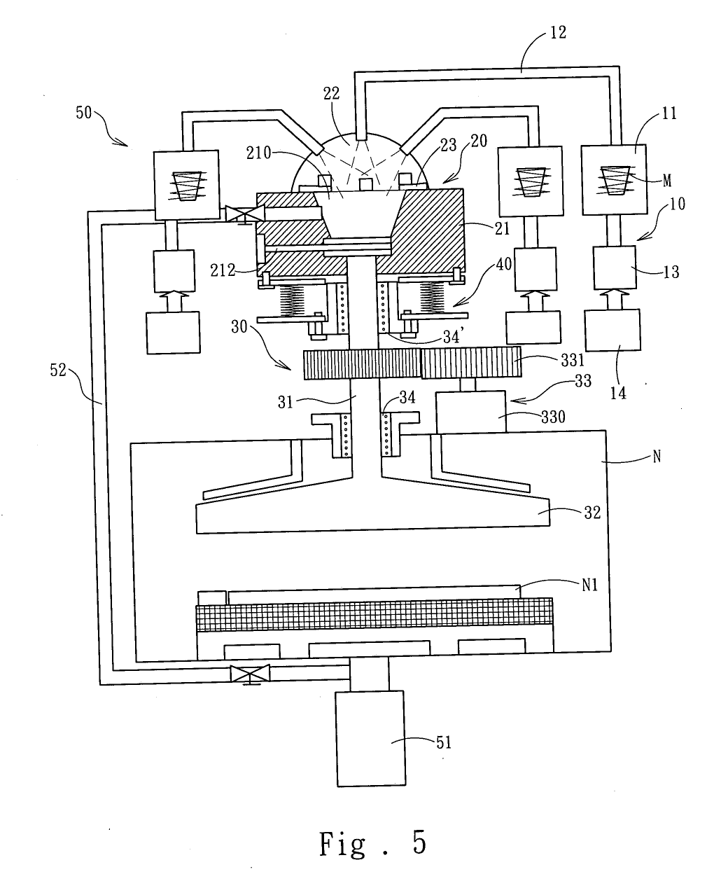

Referring to FIG. 5, it is the structural schematic diagram of an apparatus for forming a thin film according to the present invention, which includes evaporation source mechanism 10, a mixing chamber mechanism 20, a hollow revolving spindle mechanism 30, a fine turning mechanism 40, and a vacuum mechanism 50. The evaporation source mechanism 10 has at least one set of crucible 11 for storing and outputting a vapor M (the molecule of evaporation material). The crucible 11 is coupled outside to a heating pipe 12 and a mass flow controller 13. The mass flow controller 13 is coupled to a carrier gas (N₂), which is for carrying the vapor M of the crucible 11 through the heating pipe 12 to the mixing chamber mechanism 20. The mass flow controller 13 is for controlling the flow of the carrier gas and further controlling the speed of deposition.

The mixing chamber mechanism 20 has a temperature control type hollow body 21, whose interior is similar to a tank 210 of a funnel shape. There is an opening 211 in the bottom of the tank 210, and a fence gate 212 is disposed near the opening 211, which is for controlling the input and the output of the vapor M (the molecule of the evaporation material).

A concentrating chamber 22 is disposed above the temperature control hollow body 21. By the design of an arc surface, the concentrating chamber 22 is coupled to the heating pipe 12 of the crucible 11 in any direction and the vapor M is concentrated at the opening 211 properly so as to achieve an object of concentrating.

An evaporation rate monitor 23 is disposed above the temperature control type hollow body 21, for monitoring the evaporation rate according to any the evaporation material. By different evaporation rate, the temperature of the crucible 11 is adjusted so as to keep the evaporation rate being in stable state. Simultaneously, because the proportion of each evaporation material is actual known, the quantity of each evaporation material can be controlled precisely.

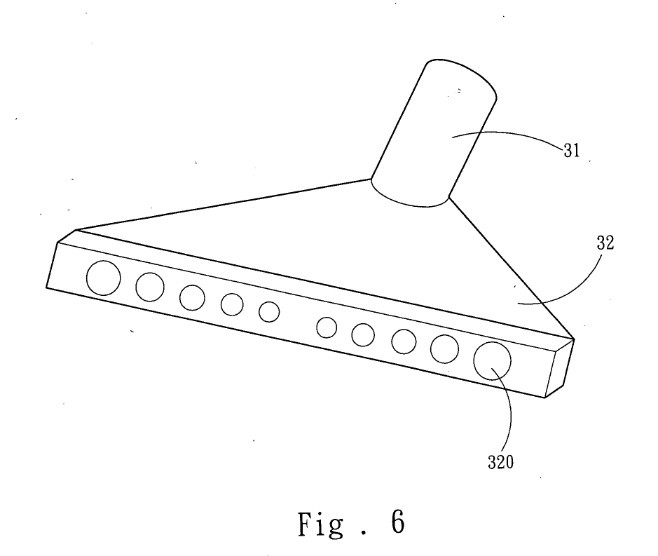

The hollow revolving spindle mechanism 30 has a hollow revolving spindle 31, whose of end is pivoted at the open of the temperature control type hollow body 21 and the other end is fixed to a revolving arm 32 of a similar fan shape. The revolving arm 32 is disposed in an evaporation chamber N. Referring to FIG. 6, it is the structural schematic diagram of the revolving arm 32 according to the present invention. A plurality of spraying holes 320 are corresponding to a substrate N1 and are disposed on one side of the revolving arm 32. The small the distance between the spraying holes and the two ends of the revolving arm 32 are, the bigger the diameters of the spraying holes are.

A transmission mean 33 includes a driving source 330 (such as a motor) and a transmitting body 331 (such as a transmitting belt). The transmitting body 331 is disposed around the hollow revolving spindle 31. The driving source 330 drives the transmitting body 331, so the transmitting body 331 drives the hollow revolving spindle 31.

At least two ferrofluid sleeves 34′, 34 are disposed around the upper and lower ends of the hollow revolving spindle 31 and respectively coupled to the temperature control type hollow body 21 and the evaporation chamber N. There are lots of tiny magnetic particles are spread uniformly in the ferrofluid sleeve 34′, 34. The magnetic particles change quickly in accordance with the change of magnetic field. By the action of the magnetic particles, the hollow revolving spindle 31 is provided with an airtight between the outside and inside hollow revolving spindle 31, so as to prevent air leakage.

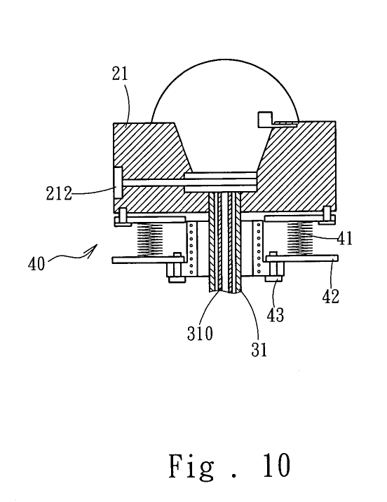

Referring to FIG. 10, the fine tuning mechanism 40 is disposed at the bottom of the temperature control type hollow body 21. The fine tuning mechanism 40 has a elastic body 41 (such as a compressed spring type bellows), a supporting plate 42, and a tuning component 43 (such as a tuning bolt). The supporting plat 42 is fixed to the ferrofluid sleeve 34′ by utilizing the tuning component 43, one end of the elastic body 41 is disposed on the supporting plate 42, and the other end of the elastic body 41 is couple to the bottom of the temperature control type hollow body 21.

By the tuning component 43, the height of the ferrofluid sleeve 34 can be adjusted to avoid different alignment between the centers of the two ferrofluid sleeve 34′, 31 deposed around the hollow revolving spindle 31 and to avoid causing the hollow revolving spindle 31 to damage the ferrofluid sleeves 34′, 34 during rotating.

The vacuum mechanism 50 has a air-removal source 51 (such as a pump) and a air-removal pipe 52, which is coupled to the inside of the evaporation chamber N and the temperature control type hollow body 21. Starting the air-removal source 51 remove the air though the air-removal pipe from the evaporation chamber N and the temperature control type hollow body 21 in order to form a vacuum state thereof.

Accordingly, the present invention is constituted by the above-mentioned mechanisms and has the following functions:

Firstly, the present invention utilizes that a carrier gas (N₂) is for carrying the vapor M of the crucible 11 through the heating pipe 12 to the mixing chamber mechanism 20, and by the design of an arc surface, the concentrating chamber 22 is coupled to the heating pipe 12 of the crucible 11 in any direction and the vapor M is concentrated at the opening 211 properly so as to achieve an object of concentrating.

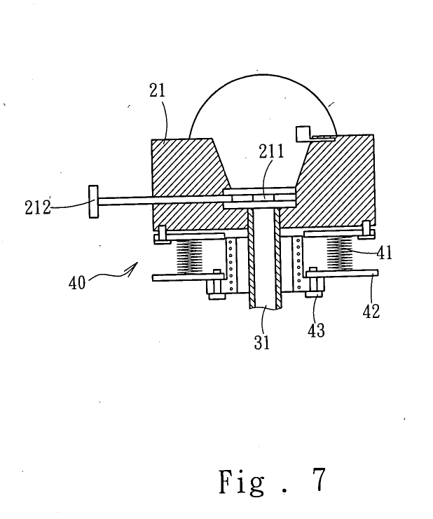

Meanwhile, by moving the fence gate 212 (Referring to FIG. 7, it is the schematic diagram of the mixing chamber mechanism according to the present invention), the vapor M (the molecule of the evaporation material) flow into the revolving arm 32 of the hollow revolving spindle 31 though the opening 211. By the spraying holes disposed on the surface of the revolving arm 32, the vapor (the molecule of the evaporation material) is sprayed on the surface of the substrate N1 and further the thin film is formed on the surface of the substrate N1. More particularly, in order to make the uniform thickness of the layer of the thin film formed on the substrate N1 according to the present invention and prevent the problem that the reappearance of an evaporation pattern is not enough, the substrate N1 is fixed during evaporation. For above reason, the present invention utilizes the transmission mean 33 drives the hollow revolving spindle 31 and the thin film is deposited on the surface of the substrate N1 by rotating the revolving arm 32, such that the thin film can be uniform at any position of the surface of the substrate N1.

Furthermore, the hollow revolving spindle 31 is coupled to the temperature control type hollow body 21 and the evaporation chamber, so as to prevent the hollow revolving spindle 31 from air leakage during rotating.

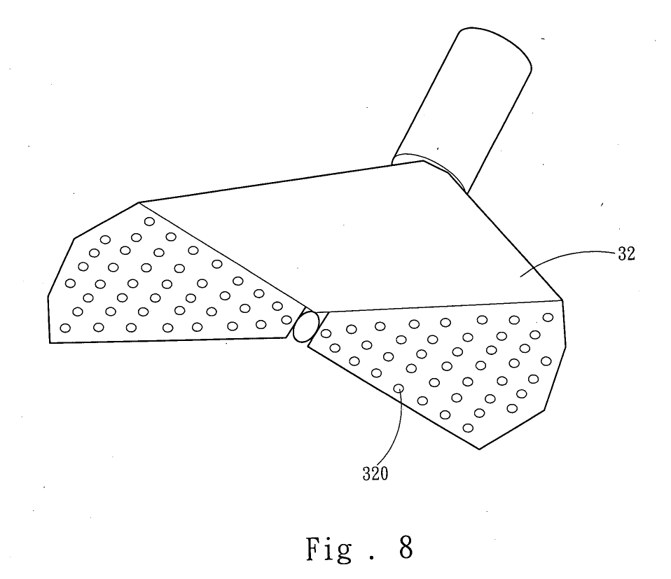

In addition, referring to FIG. 8, it is another schematic diagram of the revolving arm 32 according to the present invention. Also, the diameters of the spraying holes 320 disposed on the surface of the revolving arm 31 can be the same, but the small the distance between the spraying holes and the two ends of the revolving arm 32 are, the more the number of the spraying holes are.

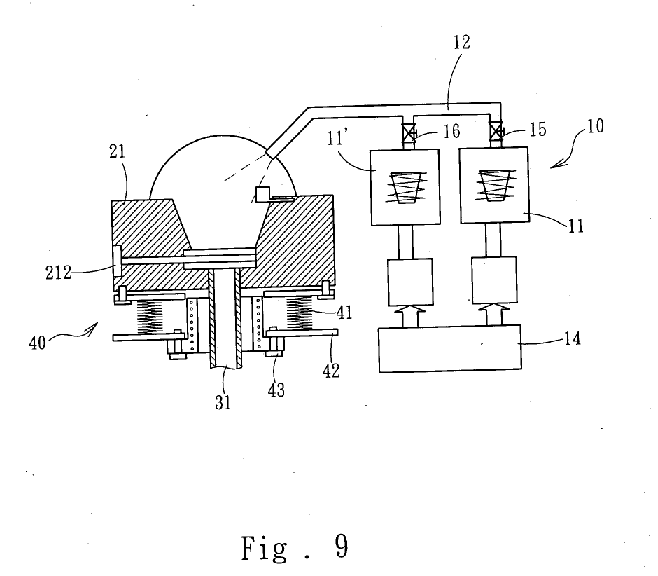

Referring to FIG. 9, it is another schematic diagram of the evaporation source mechanism 10 according to the present invention. The evaporation resource 10 has the heating pipe 12, which is coupled to two crucibles 11, 11′. By switching two control valves 15, 16, the crucible 11 is replaced with the other crucible 11′. The two crucibles 11, 11′ use the common mass flow controller 14.

Accordingly, the design of the evaporation resource 10 can manufacture the product and replace the material at the same time, so as to further decrease manufacturing time.

Referring to FIG. 10, it is another schematic diagram of the hollow spindle 31. The interior of the hollow spindle 31 is equipped with an spindle center 310 for providing the vapor M (the molecule of the evaporation material) flowing though the spindle center 310. For above reason, if cleaned necessarily, the spindle center 310 can be directly replaced with a new one, so as to avoid the cleaning of the spindle center 310.

Although the invention has been explained in relation to its preferred embodiment, it is not used to limit the invention. It is to be understood that many other possible modifications and variations can be made by those skilled in the art without departing from the spirit and scope of the invention as hereinafter claimed.

1. An apparatus for forming the thin film on an organic light-emitting diode component comprising:
an evaporation resource mechanism;
a mixing chamber mechanism coupled to said evaporation resource mechanism;
a vacuum mechanism coupled to said mixing chamber mechanism, for generating vacuum in said mixing chamber mechanism;
a fine tuning mechanism; and
a hollow revolving spindle mechanism having:
a hollow revolving spindle whose one end is pivoted to said mixing chamber mechanism;
a revolving arm coupled to the other end of said hollow revolving spindle and having a surface and a plurality of spraying holes disposed on the surface; and
a transmission mean having a driving resource and a transmitting body disposed around said hollow revolving spindle, such that said driving source drives the transmitting body and further said transmitting body drives said hollow revolving spindle.

2. The apparatus for forming the thin film on an organic light-emitting diode component according to claim 1, wherein said evaporation resource mechanism has two crucibles, two control valves, a common mass flow controller, and a heating pipe coupled to the two crucibles, such that the crucible is replaced with the other crucible by switching the two control valves, and the two crucibles use the common mass flow controller.

3. The apparatus for forming the thin film on an organic light-emitting diode component according to claim 1, wherein said mixing chamber mechanism has a temperature control type hollow body, a tank of a funnel shape disposed in the interior of the temperature control type hollow body, an opening disposed at the bottom of said temperature control type hollow body, and a fence gate disposed near the opening, so as to control the input and the output of the vapor.

4. The apparatus for forming the thin film on an organic light-emitting diode component according to claim 3, wherein the temperature control type hollow body has a concentrating chamber disposed above said temperature control hollow body, such that the concentrating chamber is coupled to the heating pipe of the crucible in any direction by the design of an arc surface and the vapor is concentrated at the opening properly to achieve an object of concentrating.

5. The apparatus for forming the thin film on an organic light-emitting diode component according to claim 3, wherein the temperature control type hollow body has an evaporation rate monitor disposed above the temperature control type hollow body for monitoring the evaporation rate according to any the evaporation material, such that the temperature of the crucible is adjusted to keep the evaporation rate being in stable state by different evaporation rate and simultaneously because the proportion of each evaporation material is actual known, the quantity of each evaporation material can be controlled precisely.

6. The apparatus for forming the thin film on an organic light-emitting diode component according to claim 1 wherein said hollow revolving spindle mechanism further has at least two ferrofluid sleeves disposed around the upper and lower ends of the hollow revolving spindle and respectively coupled to the temperature control type hollow body and the evaporation chamber so as to prevent the hollow revolving spindle from air leakage during rotating.

7. The apparatus for forming the thin film on an organic light-emitting diode component according to claim 1, wherein said fine tuning mechanism disposed at the bottom of the temperature control type hollow body and having a tuning component, a elastic body whose of one end is disposed on the supporting plate and the other end is couple to the bottom of the temperature control type hollow body, and a supporting plate fixed to the ferrofluid sleeve by utilizing the tuning component, such that the height of the ferrofluid sleeve is adjusted to avoid different alignment between the center of the two ferrofluid sleeves deposed around the hollow revolving spindle and to avoid causing the hollow revolving spindle to damage the ferrofluid sleeves during rotating.

8. The apparatus for forming the thin film on an organic light-emitting diode component according to claim 7, wherein said elastic body is a compressed spring type bellows and the tuning component is a tuning bolt.

9. The apparatus for forming the thin film on an organic light-emitting diode component according to claim 1, wherein said vacuum mechanism has a air-removal source and a air-removal pipe coupled to the inside of the evaporation chamber and the temperature control type hollow body, such that the air-removal source removes the air though the air-removal pipe from the evaporation chamber and the temperature control type hollow body to form a vacuum state.

10. The apparatus for forming the thin film on an organic light-emitting diode component according to claim 9, wherein said air-removal source is pump.

11. The apparatus for forming the thin film on an organic light-emitting diode component according to claim 1, wherein said small the distance between the spraying holes and the two ends of the revolving arm are, the bigger the diameters of the spraying holes are.

12. The apparatus for forming the thin film on an organic light-emitting diode component according to claim 1, wherein said diameters of the spraying holes are the same and the small the distance between the spraying holes and the two ends of the revolving arm are, the more the number of the spraying holes are.

13. The apparatus for forming the thin film on an organic light-emitting diode component according to claim 1, wherein said hollow revolving spindle mechanism has a spindle center disposed in the hollow spindle, for providing the vapor flowing though the spindle center, such that if cleaned necessarily, the spindle center can be directly replaced with a new one to avoid the cleaning of the spindle center.
